(19) United States
(12) Patent Application Publication
(10) Pub. No.: US 2007/0075346 A1
(43) Pub. Date: Apr. 5, 2007

(54) LIGHT EMITTING DIODE AND THE PACKAGE STRUCTURE THEREOF

(76) Inventors: Zhi-Ping Ho, Tao-Yung Hsien (TW); Fen-Ren Chien, Tao-Yung Hsien (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/309,169

(22) Filed: Jul. 5, 2006

(30) Foreign Application Priority Data
Jul. 7, 2005 (TW) 94122973

(51) Int. Cl. H01L 29/94; H01L 27/108; H01L 29/76; H01L 31/119; H01L 23/52; H01L 23/48; H01L 29/40

(52) U.S. Cl. 257/296; 257/777

(57) ABSTRACT

A light emitting diode (LED) is disclosed. The LED includes a substrate, a patterned semiconductor layer, two contact pads, a dielectric layer and a fluorescence thin film. Wherein, the patterned semiconductor layer is disposed on the substrate and suitable for emitting a first light, while the contact pads are disposed on the patterned semiconductor layer. The dielectric layer covers the patterned semiconductor layer and exposes a portion of the contact pads. In addition, the fluorescence thin film is disposed on the dielectric layer and emits a second light with a wavelength different from the first light after irradiated by the first light. Moreover, a LED package with the above-described LED is provided as well.

### CROSS-REFERENCE TO RELATED APPLICATION

This application claims the priority benefit of Taiwan application serial no. 94122973, filed on Jul. 7, 2005. All disclosure of the Taiwan application is incorporated herein by reference.

### BACKGROUND OF THE INVENTION

1. Field of Invention

The present invention relates to a luminous device and the package structure thereof, and particularly to a light emitting diode (LED) and the package structure thereof.

2. Description of the Related Art

With continuous development for increasing LED luminous efficiency in recent years, LEDs have gradually replaced the fluorescent lamps and incandescent lamps in some fields, such as light sources for scanners which require fast response, LCD back light sources, automobile dashboard lighting system, traffic lights and general lighting apparatus. In comparison with conventional lamps, LEDs have absolute advantages, such as compact size, longer lifespan, low driving voltage/current, crack-resistance, no radiation of heat during lumination, no mercury (environmentally friendly) and high luminous efficiency (power-saving). In terms of production technology and applications today, white LED received the most attention among all LEDs with colors.

White light is a light blended by a plurality of color light. The white light perceivable by human eyes comprises color lights with at least two different wavelengths. For example, blue light and yellow light are blended to generate a dual-wavelength white light, or red light, green light and blue light are blended to generate a triple-wavelength white light. Currently, white LEDs are fabricated mainly in three manners. First, it is called a triple-wavelength mode, wherein a LED chip set comprises a red LED chip, a green LED chip and a blue LED chip, by means of adjusting respective current of the three chips to generate a homogeneous white light. This mode features a high luminous efficiency but with a higher production cost. Second, it is called a dual-wavelength mode, wherein a LED chip set comprises a blue LED chip and a yellow LED chip, by means of adjusting respective current of two chips to generate homogeneous white light. This mode features a good luminous efficiency and with a lower production cost. In addition, there is a third mode, wherein a blue light generated by a blue LED is taken as a primary part and the blue light excites yellow phosphor material to generate yellow light. The blue light is then blended with the yellow light, by means of interfusing to generate white light. The third mode features a simpler production process, a lower luminous efficiency along with a lower cost. Therefore, the most of white LEDs currently are manufactured based on the third mode. Namely, the white light is generated by means of the blue light and the yellow phosphor material excited by the blue light.

FIG. 1 is a schematic cross-sectional drawing of a conventional white LED package. Referring to FIG. 1, a conventional white LED package 100 includes a frame 102, a fluorescence layer 103, a LED 106, two soldering wires 108a and 108b and an encapsulant 110. Wherein, the frame 102 is formed by two lead pins 102a and 102b and a carrier pad 102c disposed on the lead pin 102a. The LED 106 is adhered to the carrier pad 102c and electrically connected to the lead pins 102a and 102b via the soldering wires 108a and 108b, respectively. In addition, the fluorescence layer 103 enwraps the LED 106 and parts of the soldering wires 108a and 108b. The fluorescence layer 103 contains fluorescence material 104 and is made of epoxy resin and the like. The fluorescence material 104 is YAG yellow fluorescence material and the like. The encapsulant 110 encapsulates the fluorescence layer 103, the soldering wires 108a and 108b, the LED 106 and the parts of the lead pins 102a and 102b.

Note that in the white LED package 110, the distribution density of the fluorescence material 104 in the fluorescence layer 103 is hard to be controlled. When the distribution density of the fluorescence material in the fluorescence layer 103 is more even, the expected white light can be obtained by blending the blue light emitted by the LED 106 and the yellow light emitted by the fluorescence material 104. If the distribution density of the fluorescence material in the fluorescence layer 103 is not even, the obtained white light by blending the blue light emitted by the LED 106 and the yellow light emitted by the fluorescence material 104 is not as expected. Therefore, the conventional whit LED package 100 has unstable quality, which leads to low yield.

### SUMMARY OF THE INVENTION

An object of the present invention is to provide a LED capable of controlling the light color blended by two lights with two different wavelengths.

Another object of the present invention is to provide a LED package capable of controlling the light color blended by two lights with two different wavelengths.

Based on the above-described objects and the others, the present invention provides a LED, which includes a substrate, a patterned semiconductor layer, two contact pads, a dielectric layer and a fluorescence thin film. Wherein, the patterned semiconductor layer is disposed on the substrate and suitable for emitting a first light. The contact pads are disposed on the patterned semiconductor layer. The dielectric layer covers the patterned semiconductor layer and exposes a portion of the contact pads. In addition, the fluorescence thin film is disposed on the dielectric layer and suitable for emitting a second light with a wavelength different from the first light when irradiated by the first light.

The present invention provides a LED package, which includes a carrier and the above-described LED. Wherein, the LED is disposed on the carrier and electrically connected to the carrier.

In the above-described LED, the wavelength of the first light is, for example, the wavelength of blue light; while the wavelength of the second light is, for example, the wavelength of yellow light.

In the above-described LED, the wavelength of the first light is, for example, the wavelength of ultraviolet light; while the wavelength of the second light is, for example, the wavelength of red light, the wavelength of green light, the wavelength of blue light or a thereof.

In the above-described LED, the patterned semiconductor layer includes, for example, a first doping semiconductor layer, a luminous layer and a second doping semiconductor layer. Wherein, the first doping semiconductor layer is disposed on the substrate; the luminous layer is disposed on the first doping semiconductor layer, exposes a portion of the first doping semiconductor layer and is suitable for emitting the first light. In addition, the second doping semiconductor layer is disposed on the luminous layer, and the two contact pads are disposed on the first doping semiconductor layer and the second doping semiconductor layer, respectively.

In the above-described LED, the first doping semiconductor layer includes, for example, a first contact layer and a first confinement layer. The first contact layer is disposed on the substrate. The first confinement layer is disposed on the first contact layer and exposes a portion of the first contact layer, so that one of the contact pads is disposed on the first contact layer.

In the above-described LED, the second doping semiconductor layer includes, for example, a second confinement layer and a second contact layer. The second confinement layer is disposed on the luminous layer, the second contact layer is disposed on the second confinement layer, and one of the contact pads is disposed on the second contact layer.

In the above-described LED, the first doping semiconductor layer is, for example, an N-type semiconductor layer, while the second doping semiconductor layer is, for example, a P-type semiconductor layer.

The above-described LED further includes a reflection layer, which is disposed on a surface of the substrate opposite to the patterned semiconductor layer.

The above-described LED further includes a transparent conductive layer, which covers the patterned semiconductor layer and is located below the dielectric layer and below one of the contact pads.

In the present invention, the distribution of the fluorescence material inside the fluorescence thin film is more even, which enables the light color blended by the first light emitted from the patterned semiconductor layer and the second light emitted from the fluorescence thin film to be easily controlled. Therefore, the present invention is able to advance the stability of the product quality and increase the production yield.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve for explaining the principles of the invention.

FIG. 1 is a schematic cross-section drawing of a conventional white LED package.

FIG. 2 is a diagram of a LED package in an embodiment of the present invention.

FIG. 3 is a structure diagram of the LED in FIG. 2.

FIG. 4 is a structure diagram of the LED in another embodiment of the present invention.

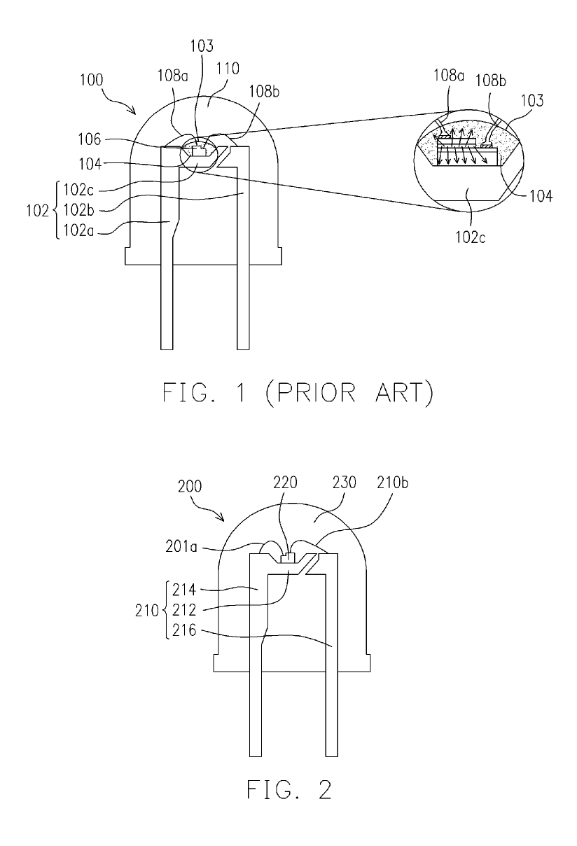

### DESCRIPTION OF THE EMBODIMENTS

FIG. 2 is a diagram of a LED package in an embodiment of the present invention and FIG. 3 is a structure diagram of the LED in FIG. 2. Referring to FIG. 2 and FIG. 3, a LED package 200 of the embodiment includes a carrier 210 and a LED 220, wherein the LED 220 is disposed on the carrier 210 and electrically connected to the carrier 210. The LED includes a substrate 221, a patterned semiconductor layer 222, two contact pads 223a and 223b, a dielectric layer 224 and a fluorescence thin film 225. The patterned semiconductor layer 222 is disposed on the substrate 221 and suitable for emitting a first light, while the contact pads 223a and 223b are disposed on the patterned semiconductor layer 222. The dielectric layer 224 covers the patterned semiconductor layer 222 and exposes a portion of the contact pads 223a and 223b. In addition, the fluorescence thin film 225 is disposed on the dielectric layer 224 and suitable for emitting a second light with a wavelength different from the first light when irradiated by the first light.

Following the above, the LED package 200 includes, for example, a soldering wire 201a and another soldering wire 201b, and the both soldering wires 201a and 201b are, for example, connected between the LED 210 and the carrier 220. In addition, the LED package 200 further includes an encapsulant 230, which encapsulates the above-described LED 220 and a portion of the carrier 210.

A more detailed structure description with regard to the above-mentioned components is as follows. The following description however is for exemplary purpose only, and shall not be construed as limiting the scope of the present invention. Anyone skilled in the art is able to make appropriate modifications and variations to the disclosed invention without departing from the scope and spirit claimed by the present invention.

The carrier 210 employed by the embodiment is, for example, a frame. The frame includes, for example, a carrier pad 212, a lead pin 214 and another lead pin 216. Wherein, the carrier pad 212 is disposed on the top of the lead pin 214 and used for carrying the LED 220. In addition, the dielectric layer 224 of the LED 220 is made of, for example, a high light-pervious material for increasing luminous efficiency of the LED 220.

The patterned semiconductor layer 222 of the LED 220 includes, for example, a first doping semiconductor layer 222a, a luminous layer 222b and a second doping semiconductor layer 222c. Wherein, the first doping semiconductor layer 222a is disposed on the substrate 221, and the luminous layer 222b is disposed on the first doping semiconductor layer 222a and exposes a portion of the first doping semiconductor layer 222a. The luminous layer 222b is suitable for emitting the above-described first light. In addition, the second doping semiconductor layer 222c is disposed on the luminous layer 222b, and the contact pads 223a and 223b are disposed on the first doping semiconductor layer 222a and the second doping semiconductor layer 222c, respectively.

The above-described first doping semiconductor layer 222a includes, for example, a first contact layer 202 and a first confinement layer 204. The first contact layer 202 is disposed on the substrate 221, and the first confinement layer 204 is disposed on the first contact layer 202 and exposes a portion of the first contact layer 202 for the contact pad 223b to be disposed on the first contact layer 202. In addition, the second doping semiconductor layer 222c includes, for example, a second confinement layer 206 and a second contact layer 208. The second confinement layer 206 is disposed on the luminous layer 222b, the second contact layer 208 is disposed on the second confinement layer 206, and the contact pad 223a is disposed on the second contact layer 208.

In the embodiment, the first doping semiconductor layer 222a is, for example, an N-type semiconductor, while the second doping semiconductor layer 222c is, for example, a P-type semiconductor. In addition, the contact pad 223a is, for example, a P-type contact pad, while the contact pad 223b is, for example, an N-type contact pad. Moreover, between the contact pad 223b and the first contact layer 202 and between the contact pad 223a and second contact layer 208, there would be good Ohm contact, respectively.

In the embodiment, the soldering wire 201a is electrically connected to the first contact layer 202 via the contact pad 223b, while the soldering wire 201b is electrically connected to the second contact layer 208 via the contact pad 223a. In the embodiment, the soldering wires 201a and 201b are gold wires with good ductility. In addition, the LED 220 further includes, for example, a reflection layer 226, which is disposed on a surface of the substrate 221 opposite to the patterned semiconductor layer 222. When the first light emitted from the luminous layer 222b and the second light emitted from the fluorescence thin film 225 irradiate the reflection layer 222b, the reflection layer 222b would reflect the first light and the second light and make them emit from the front side of the LED 220.

The distribution of the fluorescence material inside the fluorescence thin film 225 is more even, which enables the fluorescence thin film 225 to emit a more homogeneous second light. In this way, the light color blended by the first light and the second light is easily controlled. Therefore, the present invention is able to advance the stability of the product quality and increase the production yield.

In the embodiment, the wavelength of the first light emitted by the luminous layer 222b is, for example, blue light wavelength. The material of the fluorescence thin film 225 is, for example, YAG fluorescence powder or TAG fluorescence powder, both of which emit yellow light, so that by blending the first light and the second light, a white light is obtained. Note that the above-described wavelengths of the first light and the second light are for exemplary purpose only, and shall not be construed as limiting the scope of the present invention. In fact, the wavelength of the first light in the present invention can be ultraviolet wavelength, while the incorporated wavelength of the second light can be red wavelength, green wavelength, blue wavelength or a combination of the above mentioned.

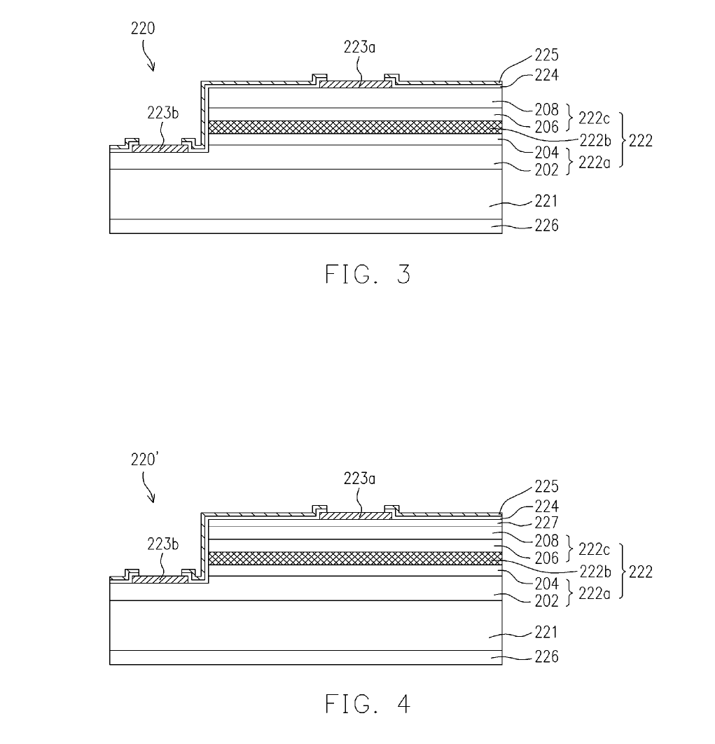

FIG. 4 is a structure diagram of the LED in another embodiment of the present invention. Referring to FIG. 4, the LED 220′ of the embodiment is similar to the above-described LED 220. The major difference is that the LED 220′ of the embodiment further includes a transparent conductive layer 227 covering a portion of the patterned semiconductor layer 222 and is located below the dielectric layer 224 and the contact pad 223a. The material of the transparent conductive layer 227 is, for example, indium tin oxide (ITO), indium zinc oxide (IZO) or other transparent conductive materials and is used for increasing luminous efficiency of the LED 220′.

In summary, the LED and the package thereof of the present invention have at least the following advantages:
1. The distribution of the fluorescence material inside the fluorescence thin film is more even, which enables the light color blended by the first light emitted from the patterned semiconductor layer and the second light emitted from the fluorescence thin film to be easily controlled. Therefore, the present invention is able to improve the stability of the product quality and increase the production yield.
2. A high light-pervious material is chosen as the material of the dielectric layer, which is capable of increasing the LED luminous efficiency.

It will be apparent to those skilled in the art that various modifications and variations can be made to the structure of the present invention without departing from the scope or spirit of the invention. In view of the foregoing, it is intended that the specification and examples to be considered as exemplary only, with a true scope and spirit of the invention being indicated by the following claims and their equivalents.

What is claimed is:

1. A light emitting diode (LED), comprising:
a substrate;
a patterned semiconductor layer, disposed on the substrate and suitable for emitting a first light;
two contact pads, disposed on the patterned semiconductor layer;
a dielectric layer, covering the patterned semiconductor layer and exposing a portion of the contact pads; and
a fluorescence thin film, disposed on the dielectric layer, wherein the fluorescence thin film is suitable for emitting a second light with a wavelength different from the first light after irradiated by the first light.

2. The LED as recited in claim 1, wherein the wavelength of the first light comprises wavelength of blue light and wavelength of the second light comprises wavelength of yellow light.

3. The LED as recited in claim 1, wherein the wavelength of the first light comprises wavelength of ultraviolet light and wavelength of the second light comprises wavelength of red light, green light, blue light or a combination thereof.

4. The LED as recited in claim 1, wherein the patterned semiconductor layer comprises:
a first doping semiconductor layer, disposed on the substrate;
a luminous layer, disposed on the first doping semiconductor layer and exposing a portion of the first doping semiconductor layer, wherein the luminous layer is suitable for emitting the first light; and
a second doping semiconductor layer, disposed on the luminous layer, wherein the contact pads are disposed on the first doping semiconductor layer and the second doping semiconductor layer, respectively.

5. The LED as recited in claim 4, wherein the first doping semiconductor layer comprises:
a first contact layer, disposed on the substrate; and
a first confinement layer, disposed on the first contact layer and exposing a portion of the first contact layer, such that one of the contact pads is disposed on the first contact layer.

6. The LED as recited in claim 4, wherein the second doping semiconductor layer comprises:
a second confinement layer, disposed on the luminous layer; and
a second contact layer, disposed on the second confinement layer and one of the contact pads is disposed on the second contact layer.

7. The LED as recited in claim 4, wherein the first doping semiconductor layer is an N-type semiconductor layer, while the second doping semiconductor layer is a P-type semiconductor layer.

8. The LED as recited in claim 1, further comprising a reflection layer disposed on a surface of the substrate opposite to the patterned semiconductor layer.

9. The LED as recited in claim 1, further comprising a transparent conductive layer covering a portion of the patterned semiconductor layer and disposed below the dielectric layer and below one of the contact pads.

10. A LED package, comprising:
a carrier;
a LED, disposed on the carrier and electrically connected to the carrier, wherein the LED comprises:
a substrate;
a patterned semiconductor layer, disposed on the substrate and suitable for emitting a first light;
two contact pads, disposed on the patterned semiconductor layer;
a dielectric layer, covering the patterned semiconductor layer and exposing a portion of the contact pads; and
a fluorescence thin film, disposed on the dielectric layer, wherein the fluorescence thin film is suitable for emitting a second light with a wavelength different from the first light after irradiated by the first light.

11. The LED package as recited in claim 10, wherein the wavelength of the first light comprises wavelength of blue light and wavelength of the second light comprises wavelength of yellow light.

12. The LED package as recited in claim 10, wherein the wavelength of the first light comprises wavelength of ultraviolet light and wavelength of the second light comprises wavelength of red light, green light, blue light or a combination thereof.

13. The LED package as recited in claim 10, wherein the patterned semiconductor layer comprises:
a first doping semiconductor layer, disposed on the substrate;
a luminous layer, disposed on the first doping semiconductor layer and exposing a portion of the first doping semiconductor layer, wherein the luminous layer is suitable for emitting the first light; and
a second doping semiconductor layer, disposed on the luminous layer, wherein the contact pads are disposed on the first doping semiconductor layer and the second doping semiconductor layer, respectively.

14. The LED package as recited in claim 13, wherein the first doping semiconductor layer comprises:
a first contact layer, disposed on the substrate; and
a first confinement layer, disposed on the first contact layer and exposing a portion of the first contact layer, such that one of the contact pads is disposed on the first contact layer.

15. The LED package as recited in claim 13, wherein the second doping semiconductor layer comprises:
a second confinement layer, disposed on the luminous layer; and
a second contact layer, disposed on the second confinement layer and one of the contact pads is disposed on the second contact layer.

16. The LED package as recited in claim 15, wherein the first doping semiconductor layer is an N-type semiconductor layer, while the second doping semiconductor layer is a P-type semiconductor layer.

17. The LED package as recited in claim 10, further comprising a reflection layer disposed on a surface of the substrate opposite to the patterned semiconductor layer.

18. The LED package as recited in claim 10, further comprising a transparent conductive layer covering a portion of the patterned semiconductor layer and disposed below the dielectric layer and below one of the contact pads.
